(19) United States
(12) Patent Application Publication
(10) Pub. No.: US 2026/0299014 A1
(43) Pub. Date: Oct. 1, 2026

(54) SEMICONDUCTOR AGING MONITORING

(71) Applicant: Intel Corporation, Santa Clara, CA (US)

(72) Inventors: Maxim LEVIT, Binyamina (IL); Eran ALTSHULER, Kiriat Ata (IL); Marcelo WOLOVELSKY, Kfar Tavor (IL); Oren ZONENSAIN, Ganei Tikva (IL)

(21) Appl. No.: 19/090,830

(22) Filed: Mar. 26, 2025

(51) Int. Cl. G01R 31/28; G01R 23/10

(52) U.S. Cl. CPC G01R 31/2884; G01R 23/10

(57) ABSTRACT

An age monitoring approach using an oscillator circuit and an identified trip voltage for the oscillator to measure frequency degradation. The trip voltage allows for the frequency degradation to be measured without having to unreasonably take temperature into account.

### BACKGROUND

Aging of modern electronic and semiconductor transistor devices, which occurs from aging and/or electrical stress, imposes serious risks for device reliable functioning during the projected service life for processors including client, server, cloud, automotive, IOT (internet of things), AI (artificial intelligence) and other processor apparatuses. Therefore, having reliable aging sensors are valuable, among other reasons, for preventing device malfunctions and preserving positive user experiences. There are other areas where having reliable and precise aging sensors is useful. For example, with accurate age (and/or stress) tracking, voltage guardband levels can be reliably reduced. For example, in the case of server products with many cores, knowledge of per-core degradation can be used, for example, by an operating system and/or system management controller to re-balance traffic and workloads between the cores to balance degradation between the cores. Aging sensors can also be used as a part of security strategies to prevent counterfeiting where used devices are passed off as new devices.

There are various different existing age monitoring solutions. For example, so-called digital aging sensors (DAS) use complicated approaches for measuring differences in delay for stressed and unstressed identical timing paths and translating the differences into voltage degradation. A disadvantage of these DAS approaches is their complexity, need for a relatively large number of fuses, calibration procedures, manufacturing and validation enablement efforts and accuracy related to temperature. Another approach counts the amount of time critical circuits are under stress by capturing and accumulating their durations in high stress situations, e.g., higher voltage/frequency modes, and translating such durations into voltage degradation levels through predefined formulas. However, such methods typically require writeable non-volatile memory to store accumulated stress information. Another disadvantage is their dependence on predefined correlation formulas, which are based on worst case units instead of individual units or unit lots, resulting in accuracy issues. Accordingly, new age monitoring techniques would be desired.

### BRIEF DESCRIPTION OF THE DRAWINGS

The disclosure may best be understood by referring to the following description and accompanying drawings that are used to illustrate embodiments. In the drawings:

FIG. 1 is a graph showing voltage-frequency curves at hot and cold temperatures for an exemplary transistor.

FIG. 2 is a graph showing a correlation between frequency degradation and compensatory offset voltage (Vmin offset) for an exemplary transistor.

FIG. 3 is a block diagram showing a processor with aging monitor circuits in accordance with some embodiments.

FIG. 4 is a block diagram showing aging monitor system circuitry in accordance with some embodiments.

FIG. 5 is a flow diagram showing a routine for adjusting a supply voltage to offset transistor degradation in accordance with some embodiments.

FIG. 6 is a flow diagram showing a routine for iteratively adjusting a supply voltage to offset transistor degradation in accordance with some embodiments.

FIG. 7 is a diagram graphically illustrating an iterative approach for voltage compensation using Vtrip oscillator supply voltages in accordance with some embodiments.

FIG. 8 illustrates an example computing system in accordance with some embodiments.

FIG. 9 illustrates a block diagram of an example processor that may have one or more cores and an integrated memory controller in accordance with some embodiments.

FIG. 10 is a block diagram illustrating a parallel processing computing system 1000 configured to implement one or more aspects of the examples described herein.

### DETAILED DESCRIPTION

In some embodiments, techniques are provided that take advantage of inverse temperature dependency (ITD) characteristics of modern, state-of-art transistors such as Fin and gate-all-around (GAA) field effect transistor (FET) devices. With such devices, it has been observed, and appreciated, that a certain voltage exists (referred hereafter as trip voltage, Vtrip) where the voltage versus switch speed is substantially independent of temperature. In some embodiments, oscillators such as ring oscillators formed from such transistors can be used with this trip voltage to monitor transistor degradation without the need for temperature compensation. In some embodiments, from time to time, ring oscillator frequency degradation (reduction) can be measured at the Vtrip voltage and then correlated with a degradation level. In some embodiments, this degradation level can be used to identify an appropriate minimum voltage (Vmin) offset to be added for supplying at least some devices in a common supply (power, voltage) domain associated with those of the monitored oscillator.

This approach can provide a simpler, less expensive temperature-independent solution. It can also be more accurate since it can be per-unit, analog in nature, and generally does not require temperature compensation.

Various embodiments can provide several beneficial technical effects including but not limited to: preventing device malfunctioning, reducing voltage reliability guardbands (which allows for power reduction, higher turbo residency, increased battery life, etc.), allowing for improved core re-balancing, and providing enhanced fraud-prevention capabilities to prevent used devices from being represented as new or newer than they actually are.

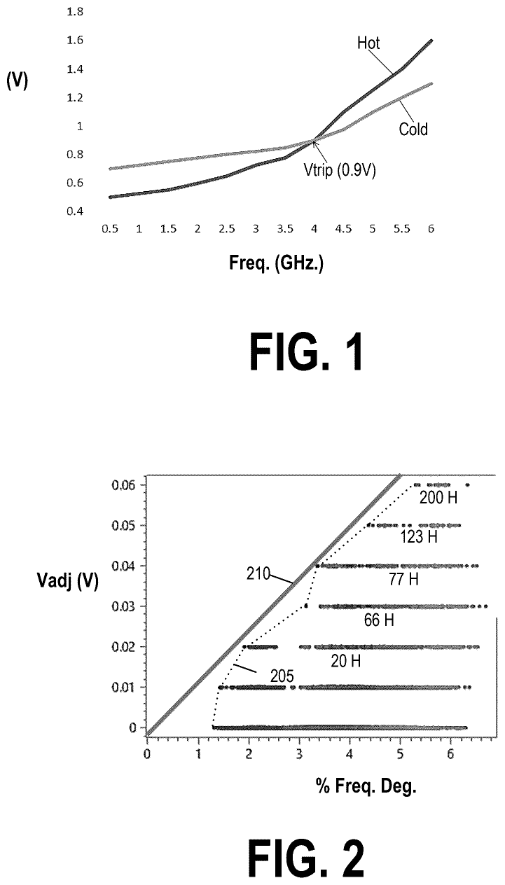

FIG. 1 is a graph showing voltage—frequency curves at hot and cold temperatures for an exemplary transistor with ITD (inverse temperature dependence) characteristics. As mentioned above, with modern high-end semiconductor transistor process nodes (e.g., Fin, GAA FETs), transistors demonstrate ITD due to opposite temperature-dependent switching speeds as affected by their threshold voltage (Vt) and their carrier mobility for lower voltage ranges (e.g., 0.4-0.8 V). So, as illustrated in the depicted curves, to generate the same frequency, the transistors need higher voltages at low temperatures, but for higher voltage ranges (e.g., 0.8-1.5 V), to generate the same frequency, they need higher voltages at the higher temperatures and lower voltages at the lower temperatures.

The above characteristics is referred to as ITD (inverse temperature dependency) as well as temperature inversion. An aspect of this characteristic is that for each transistor type, there will be a voltage where frequency will not change with temperature, i.e., frequency will be the same at this voltage across a range of its operational temperatures. This unique, intercept voltage is referred, hereafter, as a transistor's trip voltage (Vtrip). FIG. 1 illustrates the trip voltage (0.9 V) for the exemplary transistor.

The trip voltage (Vtrip) is individual for each transistor device type, depending on various die parameters (e.g., transistor type mix, transistor speed, transistor leakage, source/drain parasitic resistance and so on). Again, at the Vtrip voltage for a given transistor, frequency will be substantially the same through the device's working temperature range (e.g., 40° C.-125° C.).

In some embodiments, a transistor type's Vtrip voltage can be determined individually for each type of functional circuit block, or circuit group (e.g., compute core, graphics core, other) by measuring and generating a voltage/frequency curve at two or more temperatures and identifying the intercept point. Alternatively, predefined models (e.g., AI based) may be used with specific device parameters to predict Vtrip voltage per part or functional circuit block. Once the Vtrip voltage is identified, it can later be used to identify transistor degradation by measuring its frequency at the Vtrip voltage and then correlating the frequency reduction with an offset adjustment voltage that may be added to a previous operating point supply voltage value to compensate for the degradation.

FIG. 2 is a graph showing correlation between frequency degradation and compensatory offset adjustment (or simply offset, or adjustment) voltage (Vadj) for an exemplary transistor. The linear correlation line can be experimentally established to directly translate transistor, or oscillator, frequency degradation into a corresponding adjustment (or offset) voltage to compensate for the frequency degradation. This derived relationship can then be used by a power management system to adjust supply voltages over time to compensate for transistor aging. As shown in FIG. 2, dashed piecewise line 205 outlines worse case adjustment voltages for a group of ELT (extended life test) aged devices tested at different aging durations. A linear correlation line 210 can be established from these worse case voltage offsets and use to directly translate oscillator frequency degradation into compensatory voltage offset levels. It has been observed that strong correlations exist between RO (Ring Oscillator) frequency degradation and voltage shift across operable frequency points for the devices. With this accelerated stress example, measurements were made at specific aging points (20 H, 66 H, 77 H, 123 H, and 200 H-corresponding to overall 10 years of use life operation) and extrapolated into the depicted linear function with worst case deviations included therein. This linear function can be experimentally established during product qualification cycle. Also, after it is established, this linear function can be programmed (fused) into the product during product manufacturing and later be used for voltage adjustments as described below. In some embodiments, aging monitor (AM) circuits are disposed in integrated circuits (ICs) such as processors to monitor transistor aging and compensate for the same with appropriate supply voltage adjustments.

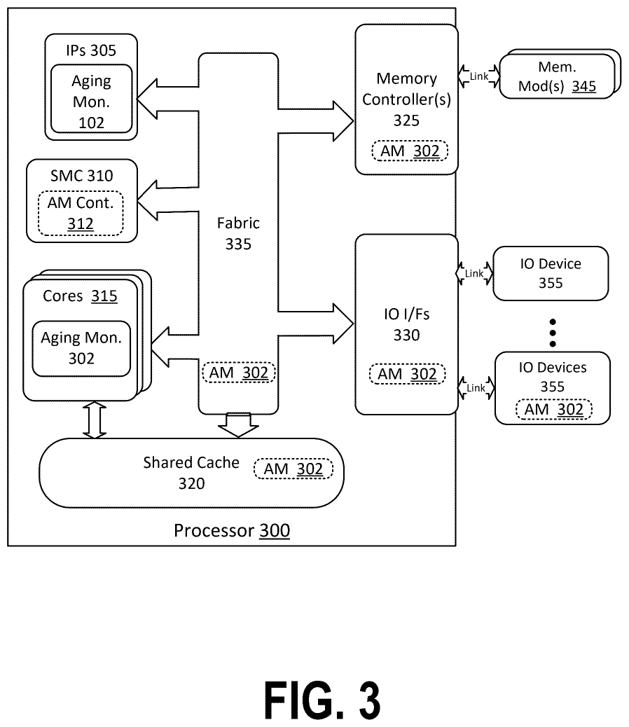

FIG. 3 is a block diagram showing a processor with aging monitor circuits in accordance with some embodiments. The processor 300 includes IP (intellectual property) circuits 305, a system management controller (SMC) 310, processing cores 315, shared cash circuitry 320, a memory controller 325, IO interface circuits 330, and system fabric 335, all coupled together as shown. Also included are memory modules 345 coupled to the memory controller 325 through memory channels and IO devices 355 coupled to the I/O interface circuits 350 through associated IO interface channels.

The processor 300 comprises at least one hardware circuit configured to execute instructions (e.g., in processor cores 315) contained in program code. The hardware circuit may be implemented with one or more integrated circuits. Examples of processor types that may be implemented with processor 300 include, but are not limited to, central processing units (CPU), array processors, vector processors, digital signal processors (DSP), field-programmable gate arrays (FPGA), application specific integrated circuits (ASIC), graphics processing units (GPU), artificial intelligence processing units (AIPU), and so forth. It should be appreciated that the processor 300 may be implemented in various different ways. For example, it may be implemented on a single die, multiple dies (dielets, chiplets), one or more dies in a common package, or one or more dies in multiple packages. Along these lines, some of the depicted blocks may be located separately on different dies or together on two or more different dies.

The IP circuits 305 are circuits that perform a particular function. An IP circuit (or IP) may be a unit of logic, circuit, cell, or chip layout that is reusable. A few examples of IP circuits include processor cores, memories, caches, floating point processors, memory controllers, bus controllers, graphics processors, transceivers, network interface controllers, and display controllers. One or more portions of a larger IP can themselves be designated as IP circuits. For example, an instruction execution unit and cache controller may be IP for a processor IP. In some embodiments, one or more IP blocks may include aging monitor circuits 302, as will be described below, to monitor and in some cases respond to transistor aging in the one or more IP blocks. Along these lines, one or more aging monitor circuits may be used to monitor aging for any circuit group, e.g., within the processor. A circuit group is a circuit, or group of circuits, with at least one common power supply rail for powering at least some of the circuits in the circuit group. Any of the blocks in the depicted processor may correspond to a circuit group or may include multiple circuit groups.

The system management controller 310 includes one or more microcontrollers, state machines and/or other logic circuits for controlling various aspects of the processor 300. For example, it may manage functions such as security, boot configuration, and power and performance including utilized and allocated power along with thermal management. The system management controller 310 may also be referred to as a P-unit, a power management unit (PMU), a power control unit (PCU), a system management unit (SMU) and the like and may include multiple system management controllers, power management units, die management controllers, etc.

In some embodiments, the system management controller 310 includes aging monitor control logic to control, oversee, and/or act in response to data from the aging monitor circuits 302. The aging monitor control logic 312 may be implemented with the system management controller running code (e.g., firmware), or it may be implemented wholly or partially with dedicated control logic circuitry such as a micro-controller or finite state machine (FSM), or with any other suitable combination of hardware and/or executing code.

The processing cores 315 comprise cores for executing code in accordance with desired functionality for the processor 100. They may comprise any suitable combination of core types such as compute (e.g., CPU) cores, graphics cores, parallel processing cores, vector processing cores, and the like, and may be implemented with differently sized core instances and/or by using the same or different instruction set architectures. Specific implementations will depend on functionality, as well as power and performance objectives. One or more of the cores 315 may include aging monitor circuits 302 for monitoring aging, circuit degradation, and/or dynamic voltage adjustment in the cores. In some embodiments, they may also or alternatively be used for adjusting voltage levels used for powering the cores, e.g., on a core by core or even finer partition level basis. The other blocks of the processor 300 may also include aging monitor circuits 302, as is indicated in the figure. Examples of aging monitor circuits are presented below.

The shared cache circuitry 320 includes one or more levels of cache memory, typically random-access memory (RAM) that is used by the other blocks in the processor including the processor cores 315. Some or all of it may be part of an overall memory system that also includes the memory modules 345. The IO devices 355 and their associated IO interface circuits 330 are coupled with the processor 300 to provide additional functionality and/or better performance capabilities. For example, they may include IO interface devices such as PCIe (Peripheral chip Interconnect express), USB (Universal Serial Bus) and/or CXL (Compute Express Link) interfaces for peripheral user interface devices, displays, accelerators, graphics cards, and the like.

The memory controller(s) 325 is coupled to the memory modules 345. The memory modules are typically made up of DRAM memory chips, and each module may include a power delivery circuit and a memory module controller to interface between the raw memory and the memory controller 325. The memory may be implemented using any suitable type such as DDR double data rate), LPDDR (Low Power DDR), and the like. Accordingly, the channels that make up the memory channels operate in conformance with whatever memory type is being implemented.

The fabric 335 is a communications network of interconnected nodes to couple to one another the various different blocks of the processor 300. In some embodiments, it facilitates high-speed data transfer and communication, which allows for the creation of unified computing systems where the different components can work together. For convenience, a single overall fabric is shown, but fabric 335 may comprise multiple different fabrics and interconnection structures such as mesh and ring networks, as well as busses and point-to-point connections. In some embodiments, it may include separate different fabrics, e.g., a main data fabric for transferring data between the blocks and a control fabric for setting parameters, reading operational states, managing operating modes, communicating telemetry, and the like. Communications for controlling and/or reading from the aging monitor circuits 302 may be carried out with one or more interconnects in fabric 335 or through other communication links within the processor.

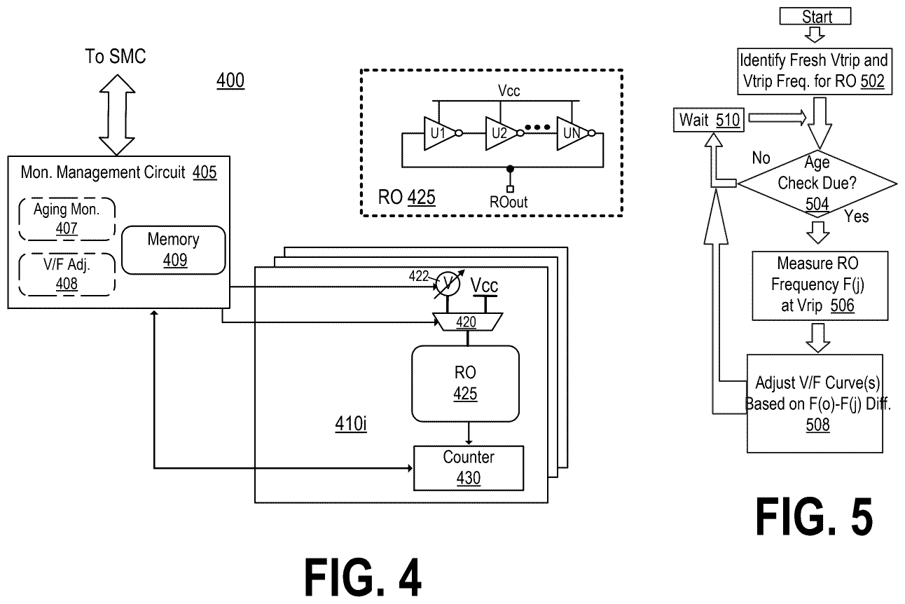

FIG. 4 is a block diagram showing aging monitor system circuitry 400 in accordance with some embodiments. One or more of the circuits 400 include a monitor management (or simply management) circuit 405 coupled with one or more age monitor (e.g., oscillator age monitor or simply oscillator monitor) circuits 410 as is shown. In the depicted embodiment, the oscillator monitor circuits are implemented with a switch 420, variable voltage supply 422, ring oscillator (RO) 425 and counter 430, coupled together as shown. The management circuit 405 controls the switch (which may be implemented with a multiplexing functioning switch network) 420 to select either the adjustable supply voltage 422 or Vcc (monitored circuit supply rail) for powering the ring oscillator 425. In some embodiments, it may control the switch to shut off the oscillator to save power. The management circuit 405 also controls the counter 430 to measure the frequency of the oscillator to monitor transistor degradation.

The ring oscillator 425 is used to determine aging of its monitored circuit group. It is allowed to age with the circuits in its group being monitored. Accordingly, ring oscillator 425 is controlled to primarily be coupled to its monitored circuit group's supply voltage (Vcc). The supply voltage (Vcc) is a supply used to power circuits within a circuit group (e.g., partition, power domain, voltage domain, etc.) such as for a core, IP, and the like that are to be monitored using ring oscillator 425, which is to be operated in concert with these circuits. While the Vcc supply rail is shown connected directly to the multiplexer 420, it should be understood that the multiplexer input may be connected to any rail, power gate or other virtual supply that may also be used for powering the circuits being monitored. That is, ring oscillator 425 should be subjected to the same, or equivalent, conditions as the circuits it is being used to monitor. Along these lines, the ring oscillator circuit, itself, should be made using the same processes as the circuits being monitored and should also be located sufficiently near such monitored circuits so as to be exposed to the same voltages and temperatures as the IP its monitoring and thus experiencing the same stress conditions.

An exemplary ring oscillator 425 is shown in the dashed box. It includes N inverters (e.g., P/N MOS inverters) coupled together as shown in a ring oscillator configuration (e.g., with an odd number of inverter stages). (As used herein, a P/N inverter is an inverter formed from a P-type transistor and an N-type transistor with their gates coupled to one another and their drains also coupled to one another.) In some embodiments, a relatively large number, e.g., 21 or more, separate inverters may be used for the ring oscillators to provide a larger sample size so as to better average out significant inverter deviations from designed-for parameters. (Note that while ring oscillator circuits are shown, any suitable oscillator design may be used, so long as the aging of its transistors can be monitored in accordance with the techniques described herein.)

The monitor management circuit 405 manages operations of the one or more age monitor circuits 410 in its associated group. This may correspond to all of the aging monitor circuits 302 in a processor, or separate management circuits may be used to manage and monitor separate aging monitor groups within a processor, e.g., in a parallel or hierarchical configuration. A monitor management circuit 405 may be implemented with any suitable circuit such as with a micro-controller, state machine(s), combinations thereof, or even by using other controllers such as a central monitor management control circuit, an system manager controller, or wholly and/or in combination with software such as control code, drivers or BIOS software running in a processor. The monitor management circuit(s) may operate autonomously, communicating measured degradation and voltage offset information to other parts of a processor (e.g., system manager controller) or they may share aging monitoring operations with one or more other controllers such as a system manager controller and/or executing OS agent.

The depicted management circuit 405 includes logic for implementing an aging monitoring logic 407 and/or logic for implementing a V/F (voltage/frequency) adjustment routine 408. The management circuit 405 also includes memory 409 to store various different code and/or information such as look-up tables or curve information for Vtrip aging and voltage adjustment versus frequency degradation aging relationships, operations control information and the like. The tables and/or curve information may alternatively be stored outside of the aging monitor, e.g., in a central management control logic 312 or elsewhere such as in fuses and/or other read-only-memory. In operation, the monitor management circuit 405, e.g., through an aging monitor logic 407, runs a routine (examples of which are described below with respect to FIGS. 5 and/or 6) to track monitored circuit group aging and to identify and utilize an appropriate voltage offset to add to supplies used for the circuit group, e.g., through a V/F adjustment logic 408. In some embodiments, for each ring oscillator monitor 410, the management circuit 405 controls the counter 430 to measure ring oscillator frequency at the ring oscillator's trip voltage (Vtrip) to assess transistor degradation and to identify a suitable adjustment (Vadj) voltage for V/F operating points for the ring oscillator's associated supply.

In some embodiments, aging monitor circuits may use ring oscillators that are free running (toggle whenever the power domain (Vcc) to which they are coupled is active), but in some embodiments, for low-power designs, they may be turned off to save power. For example, they could be run for a portion of the time their supply is active but subjected to additional stress or implemented with different transistor parameters that allow for accurate age/stress tracking of the monitored circuits within their circuit group. Along these lines, several different types of RO transistors tuned to specific frequency corners (at different Vtrip voltages) may be used to provide enhanced accuracy for voltage compensation values per operational V/F curve.

FIG. 5 is a flow diagram showing a routine for adjusting a supply voltage in accordance with some embodiments. At 502, for a ring oscillator (RO) used to monitor aging for circuitry in a supply domain (e.g., circuit group), the routine identifies its Vtrip voltage. For example, in a post-manufacturing and/or testing phase, V/F curves at two or more temperature points may be determined to identify an intersection, or cross-over, point that corresponds to the ring oscillator's Vtrip voltage.

At this Vtrip voltage, the frequency, F(o), of the ring oscillator is read at time zero (agnostic to temperature) and saved, e.g., fused during the manufacturing/testing phase. This frequency is referred to as a “fresh” frequency, measured at a “fresh” trip voltage. (Note that as used herein, time 0 is a time when the relevant transistors in an integrated circuit's circuit group are relatively new, e.g. not yet aged or aged for a limited time as a result of testing or the like prior to being commercially used.)

At 504, the routine determines if an age check is due, e.g., in accordance with a pre-designated cadence (e.g., every couple of hours, days, or even weeks). If not, the routine waits at 510 until the age check is due at 504. Once the age check is to occur, the routine proceeds from 504 to 506. Here, it measures the frequency, F(j), of the ring oscillator running at the Vtrip voltage. If the ring oscillator transistors have degraded, the frequency will have also degraded by an amount, F(o)-F(j). Based on this amount, the routine causes one or more V/F curves to be updated by adding appropriate voltage offsets commensurate with the amount of transistor degradation as determined from the Vtrip F(j) measurement. For example, it may identify the voltage adjustment from a look-up table based on the frequency difference. From here, the routine loops back to 510 and proceeds as described.

In some embodiments, as illustrated, for example, in FIG. 3, multiple oscillator aging monitors may be coupled to various power supplies in a device (e.g., processor) and be placed in several different locations including hot spots to experience the same voltage, frequency, and temperatures as the IP, itself, to be monitored. Note that in some embodiments, multiple oscillators may be used for a given supply rail and distributed throughout the associated domain. Voltage offset adjustments may then be based on an average or on a worst case frequency degradation.

It has also been observed that the Vtrip voltage is not static. That is, it changes (increases) slightly with aging, which can impact accuracy (e.g., up-to 10%). As was mentioned above, the temperature impacts in the opposite way a transistor's threshold voltage (Vt) and its charge carrier mobility vary. Temperature reduction improves (increases) mobility, while at the same time, increases its Vt level. Aging has impact on both of these components but not in the same amount. The actual amounts depend on the stress type. For example, parking/not-toggling a ring oscillator will expose the ring oscillator to bias temperature instability (BTI) transistor degradation, which changes Vt more than mobility. Therefore, it may not be correct to set the same V-trip voltage at the aged and fresh conditions because the Vtrip value, itself, will change, albeit relatively little, during aging.

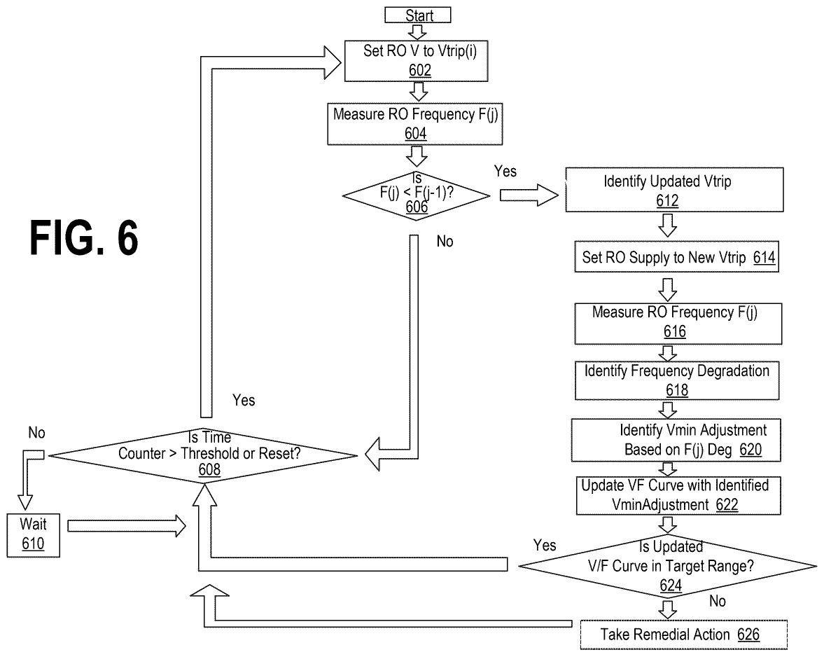

Accordingly, in some embodiments, a look-up table including Vtrip adjustment voltage information may be used to adjust the utilized Vtrip frequency measurements over time. In some embodiments, this may allow for improved accuracy, e.g., within 0.5-2%. When the ring oscillator frequency is read, the voltage may be set to the updated Vtrip voltage while temperature is not unreasonably impacting the frequency being read. But, setting the correct trip voltage requires knowledge of the amount of aging that has occurred in the circuit. However, aging is measured by the ring oscillator frequency degradation at Vtrip. This loop dependency, in some embodiments, can be addressed by effectively iterating (even just once) between starting with a previously used Vtrip point, identifying a rough degradation level based on a frequency measurement using this Vtrip value, looking up a new Vtrip value based on this frequency measurement, and then identifying a Vmin offset adjustment based on a measured frequency degradation using the updated Vtrip value. A routine for implementing such an approach is illustrated in the flow diagram of FIG. 6, discussed below. It should be appreciated, however, that while use of iterative approaches can yield more accurate degradation measurements, it is not necessary to use such approaches to achieve useful measurements, depending on particular design objectives. For example, with a five year degradation simulation, the continued use of an initial (fresh) Vtrip voltage, without updating it, resulted in an error of about 7.5%. For the same simulation, when the fresh Vtrip voltage value was updated, the error was reduced to 0.5%. So, it can be seen that depending on desired accuracy, either approach may be suitable.

FIG. 6 is a flow diagram showing a routine for iteratively adjusting a supply voltage to offset transistor degradation in accordance with some embodiments. For this routine, it is assumed that the initial (fresh) ring oscillator V-trip voltage(s) for oscillators (e.g., Ros) to be used have been determined and programmed, or otherwise made available, to a monitor management (or other control) circuit being utilized. Similarly, it is also assumed that the ring oscillator devices have been characterized, e.g., through stress testing, simulation, AI/ML analysis, and/or other, and programmed into memory, e.g., look-up table(s), formula, etc., for use by a utilized monitor management circuit performing the routine.

In some embodiments, in order to generate Vtrip and Vmin adjustment data for look-up tables or formulas, extended life tests (ELTs) may be employed to experimentally measure ring oscillator speed at both hot and cold temperatures using relatively fine granularity voltage shifts around an expected Vtrip in each read-out during the experiment to refine Vtrip correction. Such ELT experiments may also be used to refine correlations between ring oscillator frequency degradation and needed Vmin offset levels, e.g., for V/F curve operations. In some embodiments, this may even be done to identify correlations between ring oscillator frequency degradation and product Vmin VF curve offsets for each V/F frequency point used to define a V/F curve for a given circuit (e.g., core, fabric, etc.).

Returning to the routine of FIG. 6, at 602, the ring oscillator supply voltage is set to Vtrip(i), the current, or updated, trip voltage. The first time the routine runs, this will likely correspond to the fresh Vtrip value, Vtrip(0). At 604, the ring oscillator frequency, F(j), is measured for the Vtrip(i) trip voltage value. From here, at 606, the routine determines if F(j)<F(j−1), the frequency from the previously measured Vtrip, which may be a fresh Vtrip level. In some embodiments, a hysteresis may be applied, requiring the difference to be greater than some threshold level before assessing the determination as true.

If the measured F(j) is not sufficiently less than F(j−1), then the routine proceeds to 608 without updating the V/F curve for the ring oscillator monitored circuit and determines if enough time has elapsed (e.g., via timer threshold or reset mechanism) to initiate a next degradation measurement. If not, it proceeds to 610 and waits, but if so, then it loops back to 602.

Returning back to 606, if the measured frequency, F(j) was sufficiently less than the previously measured Vtrip frequency, F(j−1), then the routine proceeds to 612 and identifies an updated Vtrip value for the oscillator (e.g., RO). To do this, it may derive the new Vtrip value from a look-up table or other functional voltage generation method. At 614, the routine sets the voltage supply for the ring oscillator at the new Vtrip value, and at 616, it measures the ring oscillator frequency, F(j). From here, at 618, it identifies a frequency degradation, e.g., from the previous degraded frequency or from the fresh frequency, and at 620, based on this frequency degradation amount (or percentage), it identifies a minimum voltage (Vmin) offset adjustment to be added to the supply in the monitored domain. For example, at 622, it may update a V/F curve used for circuitry in the domain by adding the min adjustment (or offset) voltage level to voltages in the V/F operating point function.

From here, the routine proceeds to 624 and determines, or confirms, whether the updated V/F curve is within an acceptable range. This can serve as a reliability, or safety, mechanism to prevent poor performance or even malfunction, e.g., as a result of an error or unauthorized platform modification.

If the new V/F values are not within the acceptable range, then the routine, at 626, takes remedial action, e.g. issuing an alarm or resetting the V/F curve to a reliable default state. Another remedial action may be to retain the new V/F curve but notify the mask and/or thread scheduling mechanisms to re-balance circuitry (e.g., cores) so that the monitored circuitry is either used relatively less or relatively more. From here, it loops back to 608 to await the next degradation measurement check. If the updated V/F curve was within the acceptable range, then from 624, the routine proceeds to 608 without taking action at 626 and proceeds as described.

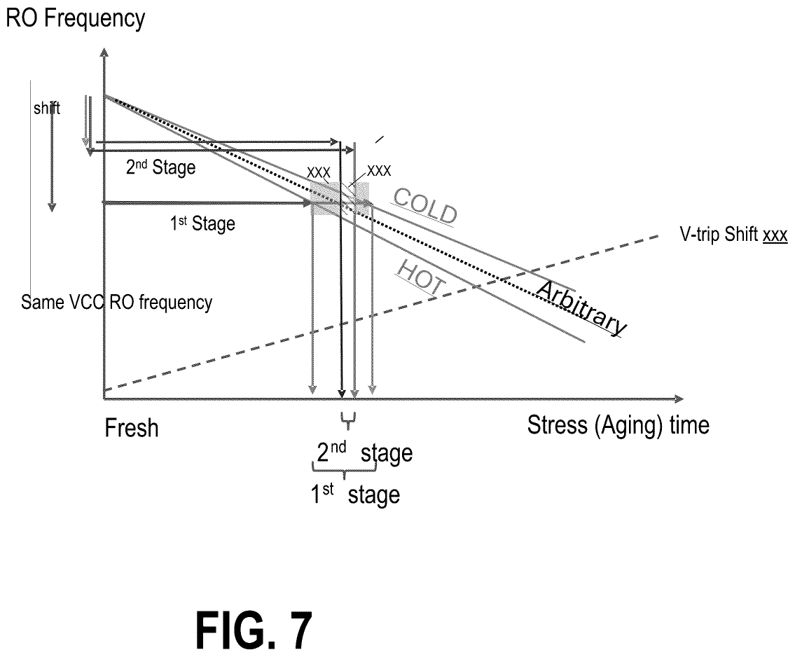

FIG. 7 is a diagram graphically illustrating an iterative approach for voltage compensation using Vtrip oscillator supply voltages in accordance with some embodiments. The graph shows how at a first stage, an updated Vtrip value that has been shifted with aging is identified. It also shows a second stage where oscillator frequency degradation is identified based on the new Vtrip level. This two-stage flow may be implemented in some embodiments of the routine of FIG. 6.

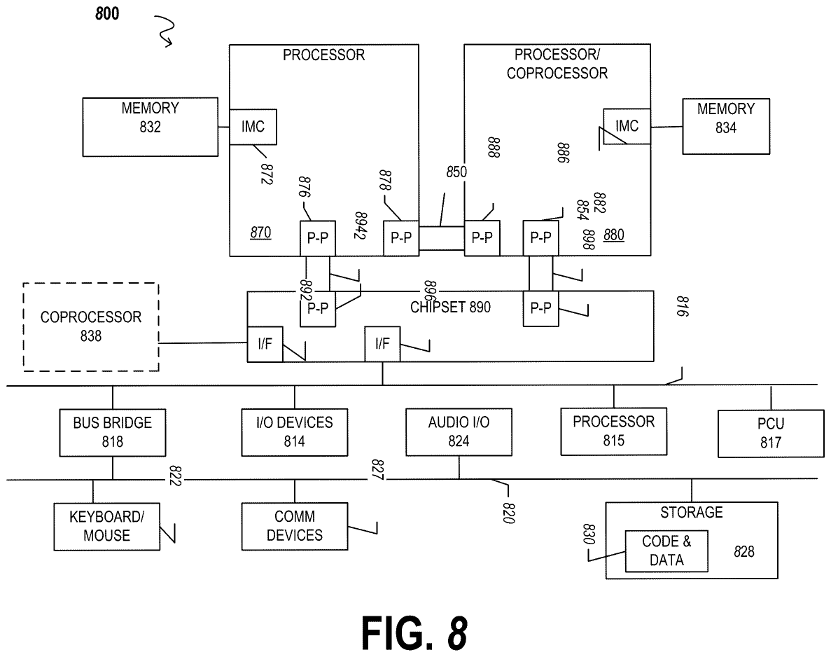

FIG. 8 illustrates an example computing system including one or more age monitoring circuits in accordance with some embodiments. Multiprocessor system 800 is an interfaced system and includes a plurality of processors including a first processor 870 and a second processor 880 coupled via an interface 850 such as a point-to-point (P-P) interconnect, a fabric, and/or bus. In some examples, the first processor 870 and the second processor 880 are homogeneous. In some examples, first processor 870 and the second processor 880 are heterogenous. Though the example system 800 is shown to have two processors, the system may have three or more processors, or be a single processor system. In some examples, the computing system is implemented, wholly or partially, with a system on a chip (SoC) or a multi-chip (or multi-chiplet) module, in the same or in different package combinations.

Processors 870 and 880 are shown including integrated memory controller (IMC) circuitry 872 and 882, respectively. Processor 870 also includes interface circuits 876 and 878, along with core sets. Similarly, second processor 880 includes interface circuits 886 and 888, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 870, 880 may exchange information via the interface 850 using interface circuits 878, 888. IMCs 872 and 882 couple the processors 870, 880 to respective memories, namely a memory 832 and a memory 834, which may be portions of main memory locally attached to the respective processors.

Processors 870, 880 may each exchange information with a network interface (NW I/F) 890 via individual interfaces 852, 854 using interface circuits 876, 894, 886, 898. The network interface 890 (e.g., one or more of an interconnect, bus, and/or fabric, and in some examples is a chipset) may optionally exchange information with a co-processor 838 via an interface circuit 892. In some examples, the co-processor 838 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 870, 880 or outside of both processors, yet connected with the processors via an interface such as P-P interconnect, such that either or both processors'local cache information may be stored in the shared cache if a processor is placed into a low power mode.

Network interface 890 may be coupled to a first interface 816 via interface circuit 896. In some examples, first interface 816 may be an interface such as a Peripheral Component Interconnect (PCI) interconnect, a PCI Express interconnect, or another I/O interconnect. In some examples, first interface 816 is coupled to a power control unit (PCU) 817, which may include circuitry, software, and/or firmware to perform power management operations with regard to the processors 870, 880 and/or co-processor 838. PCU 817 provides control information to one or more voltage regulators (not shown) to cause the voltage regulator(s) to generate the appropriate regulated voltage(s). PCU 817 also provides control information to control the operating voltage generated. In various examples, PCU 817 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 817 is illustrated as being present as logic separate from the processor 870 and/or processor 880. In other cases, PCU 817 may execute on a given one or more of cores (not shown) of processor 870 or 880. In some cases, PCU 817 may be implemented as a microcontroller (dedicated or general-purpose) or other control logic configured to execute its own dedicated power management code, sometimes referred to as P-code. In yet other examples, power management operations to be performed by PCU 817 may be implemented externally to a processor, such as by way of a separate power management integrated circuit (PMIC) or another component external to the processor. In yet other examples, power management operations to be performed by PCU 817 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 814 may be coupled to first interface 816, along with a bus bridge 818 which couples first interface 816 to a second interface 820. In some examples, one or more additional processor(s) 815, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 816. In some examples, second interface 820 may be a low pin count (LPC) interface. Various devices may be coupled to second interface 820 including, for example, a keyboard and/or mouse 822, communication devices 827 and storage circuitry 828. Storage circuitry 828 may be one or more non-transitory machine-readable storage media as described below, such as a disk drive or other mass storage device which may include instructions/code and data 830 and may implement the storage in some examples. Further, an audio I/O 824 may be coupled to second interface 820. Note that other architectures than the point-to-point architecture described above are possible. For example, instead of the point-to-point architecture, a system such as multiprocessor system 800 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

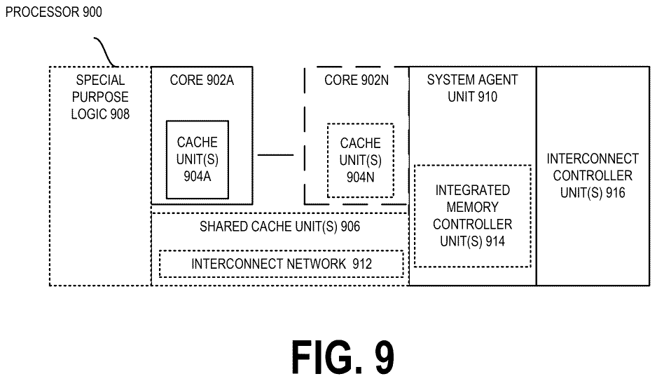

FIG. 9 illustrates a block diagram of an example processor that may have one or more cores and an integrated memory controller in accordance with some embodiments. The solid lined boxes illustrate a processor and/or SoC 900 with a single core 902(A), system agent unit circuitry 910, and a set of one or more interface controller unit(s) circuitry 916, while the optional addition of the dashed lined boxes illustrates an alternative processor and/or SoC 900 with multiple cores 902(A)-(N), a set of one or more integrated memory controller unit(s) circuitry 914 in the system agent unit circuitry 910, and special purpose logic 908, as well as a set of one or more interface controller unit(s) circuitry 916. Note that the processor and/or SoC 900 may be one of the processors 870 or 880, or co-processor 838 or 815 of FIG. 8.

Thus, different implementations of the processor and/or SoC 900 may include: 1) a CPU with the special purpose logic 908 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like(which may include one or more cores, not shown), and the cores 902(A)-(N) being one or more general purpose cores (e.g., general purpose in-order cores, general purpose out-of-order cores, or a combination of the two); 2) a co-processor with the cores 902(A)-(N) being a large number of special purpose cores intended primarily for graphics and/or scientific (throughput); and 3) a co-processor with the cores 902(A)-(N) being a large number of general purpose in-order cores. Thus, the processor and/or SoC 900 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 900 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 904(A)-(N) within the cores 902(A)-(N), a set of one or more shared cache unit(s) circuitry 906, and external memory (not shown) coupled to the set of integrated memory controller unit(s) circuitry 914. The set of one or more shared cache unit(s) circuitry 906 may include one or more mid-level caches, such as level 2 (L2), level 3 (L3), level 4 (L4), or other levels of cache, such as a last level cache (LLC), and/or combinations thereof. While in some examples interface network circuitry 912 (e.g., a ring interconnect) interfaces the special purpose logic 908 (e.g., integrated graphics logic), the set of shared cache unit(s) circuitry 906, and the system agent unit circuitry 910, alternative examples use any number of well-known techniques for interfacing such units. In some examples, coherency is maintained between one or more of the shared cache unit(s) circuitry 906 and cores 902(A)-(N). In some examples, interface controller unit(s) circuitry 916 couple the cores 902(A)-(N) to one or more other devices 918 such as one or more I/O devices, storage, one or more communication devices (e.g., wireless networking, wired networking, etc.), etc.

In some examples, one or more of the cores 902(A)-(N) are capable of multi-threading. The system agent unit circuitry 910 includes those components coordinating and operating cores 902(A)-(N). The system agent unit circuitry 910 may include, for example, power control unit (PCU) circuitry and/or display unit circuitry (not shown). The PCU may be or may include logic and components needed for regulating the power state of the cores 902(A)-(N) and/or the special purpose logic 908 (e.g., integrated graphics logic). The display unit circuitry is for driving one or more externally connected displays.

The cores 902(A)-(N) may be homogenous in terms of instruction set architecture (ISA). Alternatively, the cores 902(A)-(N) may be heterogeneous in terms of ISA; that is, a subset of the cores 902(A)-(N) may be capable of executing an ISA, while other cores may be capable of executing only a subset of that ISA or another ISA.

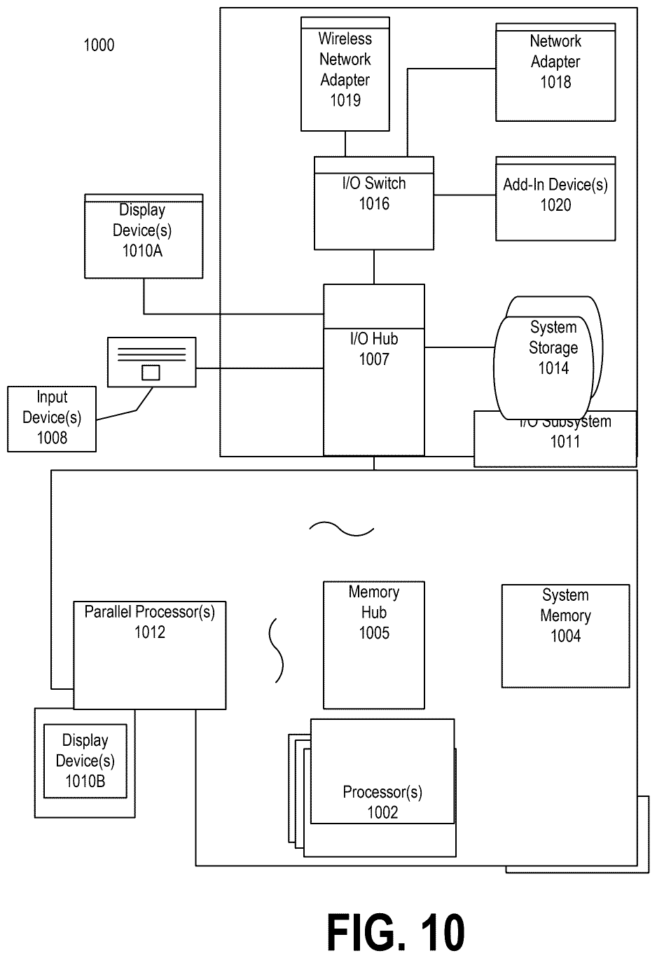

FIG. 10 is a block diagram illustrating a parallel processing computing system 1000 configured to implement one or more aspects of the examples described herein. The computing system 1000 includes a processing subsystem 1001 having one or more processor(s) 1002 and a system memory 1004 communicating via an interconnection path that may include a memory hub 1005. The memory hub 1005 may be a separate component within a chipset component or may be integrated within the one or more processor(s) 1002. The memory hub 1005 couples with an I/O subsystem 1011 via a communication link 1006. The I/O subsystem 1011 includes an I/O hub 1007 that can enable the computing system 1000 to receive input from one or more input device(s) 1008. Additionally, the I/O hub 1007 can enable a display controller, which may be included in the one or more processor(s) 1002, to provide outputs to one or more display device(s) 1010A. In some examples the one or more display device(s) 1010A coupled with the I/O hub 1007 can include a local, internal, or embedded display device.

The processing subsystem 1001, for example, includes one or more parallel processor(s) 1012 coupled to memory hub 1005 via a bus or communication link 1013. The communication link 1013 may be one of any number of standards-based communication link technologies or protocols, such as, but not limited to PCI Express, or may be a vendor specific communications interface or communications fabric. The one or more parallel processor(s) 1012 may form a computationally focused parallel or vector processing system that can include a large number of processing cores and/or processing clusters, such as a many integrated core (MIC) processor. For example, the one or more parallel processor(s) 1012 form a graphics processing subsystem that can output pixels to one of the one or more display device(s) 1010A coupled via the I/O hub 1007. The one or more parallel processor(s) 1012 can also include a display controller and display interface (not shown) to enable a direct connection to one or more display device(s) 1010B.

Within the I/O subsystem 1011, a system storage unit 1014 can connect to the I/O hub 1007 to provide a storage mechanism for the computing system 1000. An I/O switch 1016 can be used to provide an interface mechanism to enable connections between the I/O hub 1007 and other components, such as a network adapter 1018 and/or wireless network adapter 1019 that may be integrated into the platform, and various other devices that can be added via one or more add-in device(s) 1020. The add-in device(s) 1020 may also include, for example, one or more external graphics processor devices, graphics cards, and/or compute accelerators. The network adapter 1018 can be an Ethernet adapter or another wired network adapter. The wireless network adapter 1019 can include one or more of a Wi-Fi, Bluetooth, near field communication (NFC), or other network device that includes one or more wireless radios.

The computing system 1000 can include other components not explicitly shown, including USB or other port connections, optical storage drives, video capture devices, and the like, which may also be connected to the I/O hub 1007. Communication paths interconnecting the various components in FIG. 10 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL. mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 1012 may incorporate circuitry optimized for graphics and video processing, including, for example, video output circuitry, and constitutes a graphics processing unit (GPU). Alternatively or additionally, the one or more parallel processor(s) 1012 can incorporate circuitry optimized for general purpose processing, while preserving the underlying computational architecture, described in greater detail herein. Components of the computing system 1000 may be integrated with one or more other system elements on a single integrated circuit. For example, the one or more parallel processor(s) 1012, memory hub 1005, processor(s) 1002, and I/O hub 1007 can be integrated into a system on chip (SoC) integrated circuit. Alternatively, the components of the computing system 1000 can be integrated into a single package to form a system in package (SIP) configuration. In some examples at least a portion of the components of the computing system 1000 can be integrated into a multi-chip module (MCM), which can be interconnected with other multi-chip modules into a modular computing system.

It will be appreciated that the computing system 1000 shown herein is illustrative and that variations and modifications are possible. The connection topology, including the number and arrangement of bridges, the number of processor(s) 1002, and the number of parallel processor(s) 1012, may be modified as desired. For instance, system memory 1004 can be connected to the processor(s) 1002 directly rather than through a bridge, while other devices communicate with system memory 1004 via the memory hub 1005 and the processor(s) 1002. In other alternative topologies, the parallel processor(s) 1012 are connected to the I/O hub 1007 or directly to one of the one or more processor(s) 1002, rather than to the memory hub 1005. In other examples, the I/O hub 1007 and memory hub 1005 may be integrated into a single chip. It is also possible that two or more sets of processor(s) 1002 are attached via multiple sockets, which can couple with two or more instances of the parallel processor(s) 1012.

Some of the particular components shown herein are optional and may not be included in all implementations of the computing system 1000. For example, any number of add-in cards or peripherals may be supported, or some components may be eliminated. Furthermore, some architectures may use different terminology for components similar to those illustrated in FIG. 10. For example, the memory hub 1005 may be referred to as a Northbridge in some architectures, while the I/O hub 1007 may be referred to as a Southbridge.

### Example Embodiments

Illustrative examples of the technologies disclosed herein are provided below. An embodiment of the technologies may include any one or more, and any compatible combination of, the examples described below.
Example 1 is an apparatus that includes a circuit group, a management circuit, and an oscillator. The circuit group is coupled to a supply voltage rail. The oscillator includes an oscillator supply node coupled to a selectable one of an adjustable voltage supply and the supply voltage rail through a switch that is controllable by the management circuit.
Example 2 includes the subject matter of example 1, and wherein the oscillator is a ring oscillator.
Example 3 includes the subject matter of any of examples 1-2, and comprising a counter coupled to the oscillator the counter being controllable by the management circuit.
Example 4 includes the subject matter of any of examples 1-3, and wherein the oscillator and counter are part of a first age monitoring circuit that is one of a plurality of age monitoring circuits disposed in a processor to adjust one or more voltage/frequency (V/F) operating point curves for domains of the processor.
Example 5 includes the subject matter of any of examples 1-4, and wherein the management circuit is configured to identify a voltage offset for the circuit group based on a measured frequency of the oscillator when the oscillator supply node is coupled to the adjustable voltage supply set to a trip voltage level.
Example 6 includes the subject matter of any of examples 1-5, and wherein the management circuit and oscillator are part of the circuit group.
Example 7 includes the subject matter of any of examples 1-6, and wherein the management circuit is coupled to a system management control circuit.
Example 8 includes the subject matter of any of examples 1-7, and wherein the management circuit is configured to select the adjustable voltage supply to be coupled to the oscillator supply node to supply it with a trip voltage for the oscillator when it is to make a frequency degradation measurement and to select the supply voltage rail to be coupled to the oscillator supply node for at least some time when not making the frequency degradation measurement.
Example 9 includes the subject matter of any of examples 1-8, and wherein the circuit group is a processing core of a processor.
Example 10 is a processor apparatus that includes at least one circuit group including a supply rail. It also includes a ring oscillator that is part of the circuit group and that includes a ring oscillator supply node. The apparatus also includes a switch and a control circuit. The switch is coupled to the ring oscillator supply node to couple it to an adjustable supply voltage or to the supply rail. The control circuit is coupled to the switch to perform a method including: controlling the switch to select the adjustable supply voltage, controlling the adjustable supply voltage to be at a trip voltage value for the ring oscillator, measuring a frequency generated by the ring oscillator, and identifying a frequency degradation value based on the measured frequency.
Example 11 includes the subject matter of example 10, and wherein the frequency degradation value is based on a difference between the measured frequency and a fresh frequency generated by the ring oscillator.
Example 12 includes the subject matter of any of examples 10-11, and wherein the control circuit method includes identifying a voltage offset to be added to a supply rail voltage provided by the supply rail based on the frequency degradation value.
Example 13 includes the subject matter of any of examples 10-12, and wherein the switch is a multiplexer switch.
Example 14 includes the subject matter of any of examples 10-13, and wherein the control circuit includes memory with instructions to at least partially perform the method.
Example 15 includes the subject matter of any of examples 10-14, and wherein the control circuit is a system management control circuit in a processor.
Example 16 includes the subject matter of any of examples 10-15, and wherein the frequency degradation value is a first frequency degradation value, and the trip voltage is a first trip voltage, the method further including identifying a second trip voltage value based on the first frequency degradation value.
Example 17 includes the subject matter of any of examples 10-16, and wherein the method includes identifying a second frequency degradation value using the second trip voltage value.
Example 18 includes the subject matter of any of examples 10-17, and wherein the method includes adjusting voltage/frequency operating point voltage values based on the frequency degradation value.
Example 19 is a method of manufacturing a processor apparatus that includes an age monitor circuit. The method includes: making a circuit group that includes a supply voltage rail, providing a management circuit, disposing an oscillator within the circuit group, the oscillator including an oscillator supply node, and coupling the oscillator supply node, the supply voltage rail, and an adjustable voltage supply to a switch that is configured to be controlled by the management circuit to select one of the adjustable supply voltage and the supply voltage rail.
Example 20 includes the subject matter of example 19, and wherein the oscillator is a ring oscillator.
Example 21 includes the subject matter of any of examples 19-21, and comprising coupling a counter to the oscillator, the counter being controllable by the management circuit, wherein the oscillator and counter are part of the age monitoring circuit that is one of a plurality of age monitoring circuits disposed in the processor to adjust one or more voltage/frequency (V/F) operating point curves for different power domains within the processor.
Example 22 includes the subject matter of any of examples 19-21, and wherein the management circuit is configured to identify a voltage offset for the circuit group based on a measured frequency of the oscillator when the oscillator supply node is coupled to the adjustable voltage supply set to a trip voltage level.
Example 23 includes the subject matter of any of examples 19-22, and wherein the management circuit and oscillator are part of the circuit group.
Example 24 includes the subject matter of any of examples 19-23, and wherein the management circuit is coupled to a system management control circuit.
Example 25 is a method, comprising: identifying a trip voltage (Vtrip) value for an oscillator circuit used to monitor aging for circuitry in a supply domain, supplying power to the oscillator at the Vtrip voltage value, reading a frequency generated by the oscillator, and updating at least one voltage supply level for the supply domain based on the measured frequency.
Example 26 includes the subject matter of example 25, and wherein updating at least one voltage supply level includes identifying a frequency difference between the measured frequency and a fresh frequency.
Example 27 includes the subject matter of any of examples 25-26, and wherein updating at least one voltage supply level includes identifying a voltage adjustment value from a look-up table based on the frequency difference.
Example 28 includes the subject matter of any of examples 25-27, and wherein identifying the trip voltage includes generating V/F curves at two or more temperature points.
Example 29 includes the subject matter of any of examples 25-28, and wherein the trip voltage is programmed into a processor.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a circuit group coupled to a supply voltage rail;
a management circuit;
an adjustable voltage supply; and
an oscillator including an oscillator supply node coupled to the adjustable voltage supply or the supply voltage rail through a switch that is controllable by the management circuit.

2. The apparatus of claim 1, wherein the oscillator is a ring oscillator.

3. The apparatus of claim 1, further comprising a counter coupled to the oscillator, wherein the counter is capable of being controlled by the management circuit.

4. The apparatus of claim 1, wherein the oscillator and counter are part of a first monitoring circuit that is one of a plurality of first monitoring circuits associated with a processor to adjust one or more voltage/frequency (V/F) operating point curves for domains of the processor.

5. The apparatus of claim 1, wherein the management circuit is configured to identify a voltage offset for the circuit group based on a measured frequency of the oscillator when the oscillator supply node is coupled to the adjustable voltage supply set to a trip voltage level.

6. The apparatus of claim 1, wherein the management circuit and oscillator are disposed within the circuit group.

7. The apparatus of claim 6, wherein the management circuit is coupled to a system management control circuit.

8. The apparatus of claim 1, wherein the management circuit is configured to select the adjustable voltage supply to be coupled to the oscillator supply node to supply it with a trip voltage for the oscillator when it is to make a frequency degradation measurement and to select the supply voltage rail to be coupled to the oscillator supply node for at least some time when not making the frequency degradation measurement.

9. The apparatus of claim 1, wherein the circuit group is a processing core of a processor.

10. An apparatus, comprising:
at least one circuit group including a supply rail and ring oscillator, wherein the ring oscillator further comprises a ring oscillator supply node;
a switch coupled to the ring oscillator supply node to couple it to an adjustable supply voltage or to the supply rail; and
a control circuit coupled to the switch and capable of:
controlling the switch to select the adjustable supply voltage,
controlling the adjustable supply voltage to be at a trip voltage value for the ring oscillator,
measuring a frequency generated by the ring oscillator, and
identifying a frequency degradation value based on the measured frequency.

11. The apparatus of claim 10, wherein the frequency degradation value is based on a difference between the measured frequency and a frequency generated by the ring oscillator.

12. The apparatus of claim 10, wherein the control circuit is further capable of: identifying a voltage offset to be added to a supply rail voltage provided by the supply rail based on the frequency degradation value.

13. The apparatus of claim 10, wherein the switch is a multiplexer switch.

14. The apparatus of claim 10, wherein the control circuit includes memory with instructions to cause the control circuit to at least partially perform the method.

15. The apparatus of claim 14, wherein the control circuit is a system management control circuit in a processor.

16. The apparatus of claim 10, wherein the frequency degradation value is a first frequency degradation value, and the trip voltage is a first trip voltage, the method further including identifying a second trip voltage value based on the first frequency degradation value.

17. The apparatus of claim 16, wherein the method includes identifying a second frequency degradation value using the second trip voltage value.

18. The apparatus of claim 10, wherein the method includes adjusting voltage/frequency operating point voltage values based on the frequency degradation value.

19. A process of making a processor that includes an age monitor circuit, comprising:
making a circuit group that includes a supply voltage rail;
providing a management circuit;
disposing an oscillator within the circuit group, the oscillator including an oscillator supply node; and
coupling the oscillator supply node, the supply voltage rail, and an adjustable voltage supply to a switch that is configured to be controlled by the management circuit to select one of the adjustable supply voltage or supply voltage rail.

20. The process of claim 19, comprising coupling a counter to the oscillator, the counter being controllable by the management circuit, wherein the oscillator and counter are part of the age monitoring circuit that is one of a plurality of age monitoring circuits disposed in the processor to adjust one or more voltage/frequency (V/F) operating point curves for different power domains within the processor.
